(19) United States
(12) Patent Application Publication
(10) Pub. No.: US 2025/0130297 A1
(43) Pub. Date: Apr. 24, 2025

(54) MAGNETIC SENSOR USING SPIN ORBIT TORQUE AND SENSING METHOD USING SAME

(71) Applicants: Hyundai Motor Company, Seoul (KR); Kia Corporation, Seoul (KR)

(72) Inventors: Joon-Hyun KWON, Hwaseong-si (KR); Ji-Sung LEE, Suwon-si (KR); Han-Saem LEE, Seoul (KR); Su-Jung NOH, Seoul (KR)

(73) Assignees: Hyundai Motor Company, Seoul (KR); Kia Corporation, Seoul (KR)

(21) Appl. No.: 18/990,339

(22) Filed: Dec. 20, 2024

Related U.S. Application Data
(62) Division of application No. 17/710,123, filed on Mar. 31, 2022.

(30) Foreign Application Priority Data
Dec. 29, 2021 (KR) 10-2021-0190971

(51) Int. Cl. G01R 33/07; G01R 33/00

(52) U.S. Cl. CPC G01R 33/075; G01R 33/0052

(57) ABSTRACT

A magnetic sensor using a spin-orbit torque (SOT) and a sensing method using the same, include an SOT channel layer made of a heavy metal material, a ferromagnetic layer stacked on the SOT channel layer, and a protective layer stacked on the ferromagnetic layer, wherein an SOT is generated due to a current applied to the SOT channel layer to vary magnetization of the ferromagnetic layer, and the magnetic sensor which utilizes an SOT with a fast response speed and high sensitivity using a simplified metal thin film structure in which the SOT is generated is provided.

### CROSS-REFERENCE(S) TO RELATED APPLICATIONS

This application is the divisional application of U.S. patent application Ser. No. 17/710,123 filed on Mar. 31, 2022, which claims priority to Korean Patent Application No. 10-2021-0190971, filed on Dec. 29, 2021, the entire contents of which is incorporated herein for all purposes by this reference.

### BACKGROUND OF PRESENT DISCLOSURE

### Field of Present Disclosure

The present disclosure relates to a magnetic sensor, and to a magnetic sensor using a spin-orbit torque (SOT) and a sensing method using the same.

### Description of Related Art

As a typical magnetic sensor applied to a vehicle, there are a Hall sensor and a tunneling magnetoresistance (TMR) sensor.

When a magnetic field is applied to a conductor through which a current flows, the Hall sensor may detect a direction and a magnitude of the magnetic field using a Hall effect in which a voltage is generated in a direction perpendicular to the current and the magnetic field.

The TMR sensor has a magnetic tunneling junction (MTJ) structure in which an oxide film is inserted between two magnetic layers and may detect a magnitude of the magnetic field through a variation in magnetoresistance which occurs as magnetization of a sensing layer is varied in response to a variation in external magnetic field.

However, because the Hall sensor outputs a voltage according to movement of electrons, a response speed is slow and sensitivity is low, and there is a disadvantage in that a structure in which a magnet is inserted to overcome the low response speed and the low sensitivity is complicated.

Furthermore, because the TMR sensor has a complicated structure and the inserted oxide film has low durability, there is a concern in that leakage and breakdown occur due to a strong current or voltage.

The information included in this Background of the present disclosure section is only for enhancement of understanding of the general background of the present disclosure and may not be taken as an acknowledgement or any form of suggestion that this information forms the prior art already known to a person skilled in the art.

### BRIEF SUMMARY OF PRESENT DISCLOSURE

Various aspects of the present disclosure are directed to providing a spin-orbit torque (SOT) magnetic sensor with a fast response speed and high sensitivity using a simplified metal thin film structure in which an SOT is generated.

Other objects and advantages of the present disclosure may be understood by the following description and become apparent with reference to the exemplary embodiments of the present disclosure. Also, it is obvious to those skilled in the art to which the present disclosure pertains that the objects and advantages of the present disclosure may be realized by the means as claimed and combinations thereof.

In accordance with an exemplary embodiment of the present disclosure, there is provided a magnetic sensor using a spin-orbit torque (SOT), which includes an SOT channel layer made of a heavy metal material, a ferromagnetic layer stacked on the SOT channel layer, and a protective layer stacked on the ferromagnetic layer, wherein an SOT is generated due to a current applied to the SOT channel layer to vary magnetization of the ferromagnetic layer.

Furthermore, the ferromagnetic layer may be made of a perpendicular magnetic anisotropy material.

Furthermore, the varied magnetization of the ferromagnetic layer may be in a direction perpendicular to a flat surface formed by the ferromagnetic layer.

The magnetic sensor may further include a sensing portion formed to be parallel to a flat surface formed by the ferromagnetic layer, measure a voltage of a component perpendicular to the direction of the current, and confirm a magnetization state.

Furthermore, when an external auxiliary magnetic field in a direction parallel to the direction of the current is applied after the SOT occurs, a magnetization switching may occur.

Furthermore, a magnetization state due to the magnetization switching may be parallel to the direction of the current, and when a magnetic field in a direction opposite to a direction of the external auxiliary magnetic field is applied, the magnetization switching may be performed again, and the magnetization state may be maintained unless a magnetic field is applied in a direction parallel to the direction of the current and in a direction opposite to the direction of the external auxiliary magnetic field.

An output signal measured by the sensing portion may be a digital signal.

Next, in accordance with an exemplary embodiment of the present disclosure, there is provided a sensing method of a magnetic sensor using a spin-orbit torque (SOT), which includes applying a current to the SOT channel layer of the magnetic sensor using an SOT, applying an external auxiliary magnetic field in a direction parallel to a direction of the current after the SOT occurs, and measuring a voltage of a component parallel to a flat surface formed by the ferromagnetic layer and perpendicular to a direction of the current.

Here, the ferromagnetic layer may be made of a perpendicular magnetic anisotropy material.

Furthermore, an output signal measured in the measuring of the voltage may be a digital signal.

The methods and apparatuses of the present disclosure have other features and advantages which will be apparent from or are set forth in more detail in the accompanying drawings, which are incorporated herein, and the following Detailed Description, which together serve to explain certain principles of the present disclosure.

### BRIEF DESCRIPTION OF THE DRAWINGS

FIG. 1 is a diagram illustrating various structures using a magnetic sensor according to an exemplary embodiment of the present disclosure.

FIG. 2 is a schematic diagram illustrating a magnetic sensor using a spin-orbit torque (SOT) according to an exemplary embodiment of the present disclosure.

FIG. 3 is a diagram for describing a method of measuring anomalous Hall effect (AHE) resistance.

FIG. 4 is a diagram illustrating an example of AHE resistance.

FIG. 5 and FIG. 7 are diagrams illustrating examples of magnetization switching measurement due to current application using an SOT.

FIG. 6 and FIG. 8 are graphs showing results measured through the AHE resistance.

FIG. 9 is a diagram for describing a difference between a magnetization switching using a magnetic field and a current applied magnetization switching using an SOT.

FIG. 10 is a schematic diagram illustrating a motor for a vehicle.

FIG. 11 is a diagram illustrating a portion of the motor and a magnetic sensor configured for sensing the motor for a vehicle according to an exemplary embodiment of the present disclosure.

FIG. 12, and FIG. 13 are diagrams illustrating a comparison of the use amount of permanent magnets.

FIG. 14, and FIG. 15 are diagrams illustrating a comparison of magnetization of the permanent magnets.

FIG. 16 is a diagram illustrating an example of a rotation speed measurement in the exemplary embodiment of FIG. 11.

FIG. 17 is a diagram illustrating an example of an output signal.

FIG. 18 is a diagram illustrating a magnetic sensor configured for sensing the motor for a vehicle of FIG. 10 according to another exemplary embodiment of the present disclosure.

FIG. 19 is a diagram illustrating an example of a rotation speed measurement in the exemplary embodiment of FIG. 18.

FIG. 20 is a diagram illustrating an example of an output signal.

FIG. 21 is a diagram illustrating an example of measurement of an angle (position) in the exemplary embodiment of FIG. 18.

It may be understood that the appended drawings are not necessarily to scale, presenting a somewhat simplified representation of various features illustrative of the basic principles of the present disclosure. The specific design features of the present disclosure as included herein, including, for example, specific dimensions, orientations, locations, and shapes will be determined in part by the particularly intended application and use environment.

In the figures, reference numbers refer to the same or equivalent parts of the present disclosure throughout the several figures of the drawing.

### DETAILED DESCRIPTION

Reference will now be made in detail to various embodiments of the present disclosure(s), examples of which are illustrated in the accompanying drawings and described below. While the present disclosure(s) will be described in conjunction with exemplary embodiments of the present disclosure, it will be understood that the present description is not intended to limit the present disclosure(s) to those exemplary embodiments of the present disclosure. On the other hand, the present disclosure(s) is/are intended to cover not only the exemplary embodiments of the present disclosure, but also various alternatives, modifications, equivalents and other embodiments, which may be included within the spirit and scope of the present disclosure as defined by the appended claims.

To fully understand the present disclosure and operational advantages of the present disclosure and objects attained by practicing the present disclosure, reference may be made to the accompanying drawings that illustrate exemplary embodiments of the present disclosure and to the description in the accompanying drawings.

In describing exemplary embodiments of the present disclosure, known technologies or repeated descriptions may be reduced or omitted to avoid unnecessarily obscuring the gist of the present disclosure.

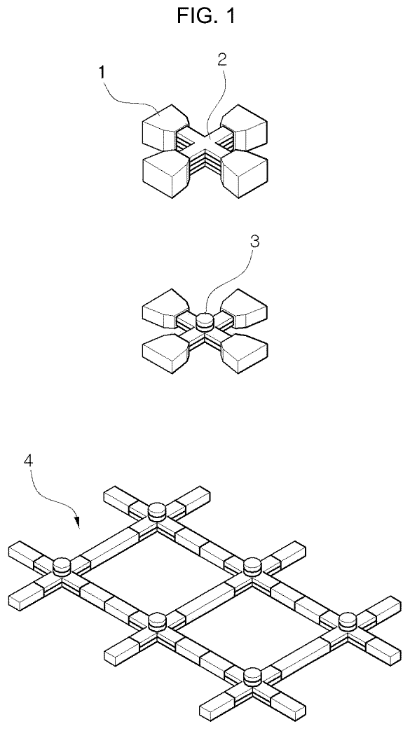

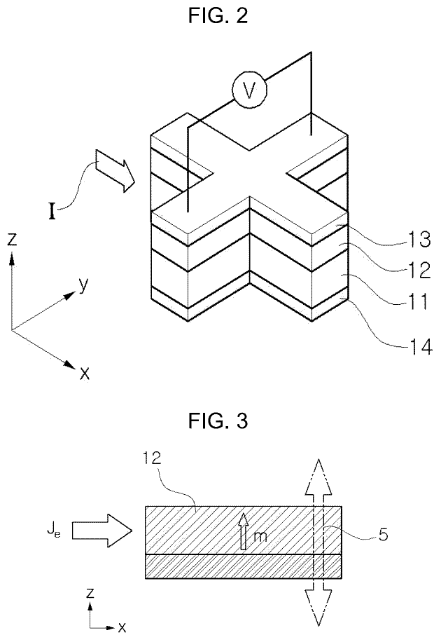

FIG. 1 is a diagram illustrating various structures using a magnetic sensor according to an exemplary embodiment of the present disclosure, and FIG. 2 is a schematic diagram illustrating a magnetic sensor using a spin-orbit torque (SOT) according to an exemplary embodiment of the present disclosure.

Hereinafter, a magnetic sensor using an SOT according to an exemplary embodiment of the present disclosure will be described with reference to FIG. 1 and FIG. 2.

As shown in FIG. 1, a sensor structure using an SOT may have a single device in a form of a Hall bar 2 or a cell 3 on which a circular or quadrangular thin film layer is stacked or have a grid array 4 connected by an electrode. The single device includes heavy metal layer channels in a form of a cross, and a measurement terminal 1 is connected to an end portion of each channel. A measurement terminal is also connected to an end portion of each line of the grid array 4 and may be connected to a printed circuit board (PCB) through a wiring method to read an output signal for each structure.

The measurement terminal employs an Au or Cu electrode, and to increase adhesive strength to the existing thin film and the existing wafer, a metal layer made of Ta, Ti, or Cr is deposited on a bottom portion of the measurement terminal.

FIG. 2 is a three-dimensional schematic diagram illustrating an SOT sensor structure based on a structure of the Hall bar 2 provided in FIG. 1, and a Hall bar structure-based magnetic sensor according to an exemplary embodiment of the present disclosure will be described.

A ferromagnetic layer 12, which is made of Co or CoFeB, capable of securing perpendicular magnetic anisotropy is bonded on an SOT channel layer 11 made of a heavy metal such as Ta, Pt, W, or Hf, and a protective layer 13 made of MgO, Ru, or Ta is formed on the ferromagnetic layer 12. A buffer layer 14 for increasing adhesive strength to the wafer is used below the SOT channel layer 11.

When a direct-current (DC) charge current I is injected into the SOT channel layer 11, spins with polarization in a-y direction and a +y direction move in a +z direction and a −z direction due to a spin Hall effect, and the spins moving to an interface between the SOT channel layer 11 and the ferromagnetic layer 12 are accumulated and then injected into the ferromagnetic layer 12.

The movement of the injected spin is known as a spin current, and the magnetization is varied due to an SOT, which is generated by the spin current, and an auxiliary external magnetic field in a surface direction thereof.

In the instant case, the magnetization has a +z direction component or a −z direction component, and variations in voltage and resistance according to a direction may be confirmed by measuring a voltage and resistance due to an anomalous Hall effect (AHE). Magnitudes and polarities of the voltage and the resistance due to the AHE may be detected so that a separate sensing part measures a voltage V of a component perpendicular to a direction in a surface with respect to a flow of a current I as shown in the drawing.

FIG. 3 illustrates a method of measuring AHE resistance of a perpendicular magnetization magnetic layer having perpendicular magnetic anisotropy. In general, the perpendicular magnetization magnetic layer may be manufactured using a Co or Fe alloy and a material, such as Ta or Pt, as a buffer layer, and then through heat treatment, a characteristic of the perpendicular magnetization magnetic layer may be improved. A direction (polarity) of perpendicular magnetization m is as shown in the drawing, and the perpendicular magnetization m is aligned in the +z and −z directions due to an external magnetic field 5 in a vertical direction. A direction of the magnetization m may be detected by measuring a voltage in the y direction in the surface due to AHE when a current flows in an x direction in the surface.

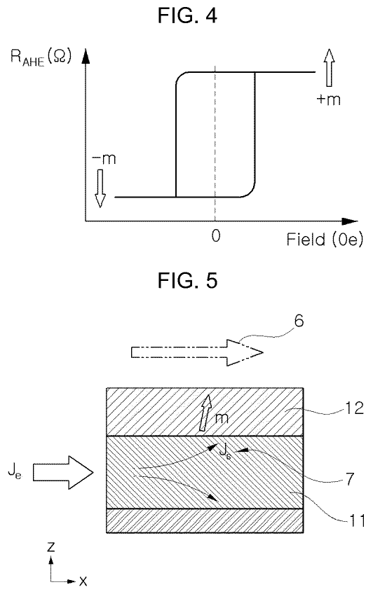

FIG. 4 is an example of AHE resistance measured while an external magnetic field 5 in a vertical direction is applied in the +z and −z directions. Here, the AHE resistance may also be expressed as an AHE voltage. In the present example, when resistance is high, the resistance is indicated as magnetization +m, and the resistance is low, the resistance is indicated as magnetization −m, but a polarity may be changed according to a measurement condition.

Next, FIG. 5 illustrates a structure in which a heavy metal layer is deposited on a lower portion of the perpendicular magnetization magnetic layer of FIG. 3. In the instant case, when a charge current flows due to the above-described spin Hall effect, a spin current 7 is generated in the +z direction, and an SOT is generated due to the spin current 7. However, only the SOT cannot vary the magnetization of the perpendicular magnetization magnetic layer in a stable state. In the instant case, when an external auxiliary magnetic field 6 is applied in the +x direction, the magnetization m loses an equilibrium state (magnetization is inclined in the +x direction) and magnetization is varied due to the SOT. This is referred to as a magnetization switching due to current application.

For occurrence of the magnetization switching due to a current, 1) a current which is greater than or equal to a critical current Ic at which a switching may occur should be injected, and 2) an external auxiliary magnetic field 6 having a sufficient magnitude, which is capable of breaking an equilibrium state of the perpendicular magnetization magnetic layer, should be applied.

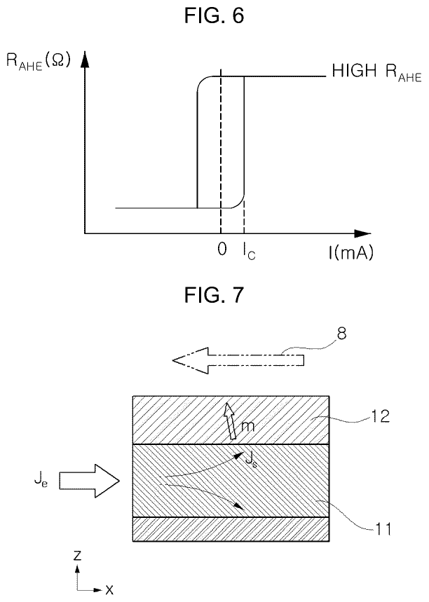

FIG. 6 is an example of a result of measuring whether the magnetization switching is performed according to an amount of an injected current through AHE resistance. When the injected current is increased in a state of applying a constant auxiliary magnetic field, the AHE resistance is varied when the injected current is greater than or equal to the critical current Ic. Through the above description, it may be seen that the magnetization switching is performed.

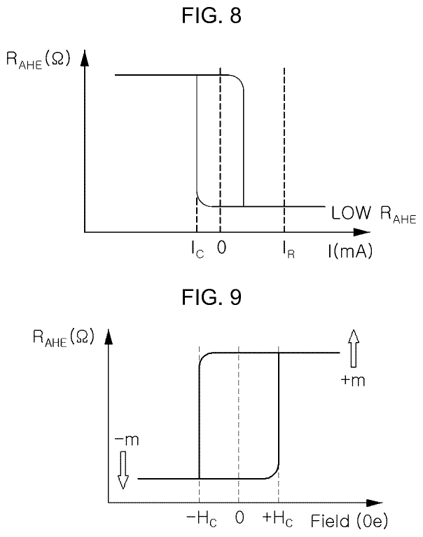

FIG. 7 is a schematic diagram illustrating a state in which the magnetization m is inclined in the −x direction when an external auxiliary magnetic field 8 is applied in the −x direction, and FIG. 8 is an example illustrating a variation in AHE resistance according to an injected current in the above state. As may be confirmed from FIG. 8, the variation in AHE resistance exhibits a line symmetric shape with respect to the magnetic hysteresis curve of FIG. 6, and it may be seen that the variation in AHE resistance is affected by the inclination direction of the magnetization m according to the direction of the external auxiliary magnetic field 8. Therefore, assuming magnetization states of magnetization −m when having a low R_{AHE} and magnetization +m when having a high R_{AHE}, when the external auxiliary magnetic field 8 is in the +x direction, a critical current Ic of −m→+m has a (+) polarity, and when the external auxiliary magnetic field 8 is in the −x direction, a critical current Ic of −m→+m has a (−) polarity.

Furthermore, when a reference current I_{R} having a constant amount which is sufficiently greater than an absolute value of the critical current Ic is injected, it may be seen that the magnetization m has a high R_{AHE} when the external auxiliary magnetic field 8 is in the +x direction and has a low R_{AHE} when the external auxiliary magnetic field 8 is in the −x direction. That is, the direction and the presence or absence of the external magnetic field may be confirmed through resistance using the reference current including a constant amount, and because such a variation is due to the magnetization switching, the variation occurs within several nanoseconds (ns).

Generally, to vary the magnetization, it is necessary to apply strength of a magnetic field which is greater than or equal to ±H_{C} indicated in FIG. 9. In the instant case, H_{C} is referred to as a coercive force and depends on a material and a structure. Varying the magnetization refers that a precessional motion of stable magnetization (equilibrium state) in one direction should be overcome, and in the magnetization switching due to an external magnetic field, all energy required for switching should be covered by only the external magnetic field.

However, in the case of a switching using an SOT, magnetization is varied using the SOT and an external auxiliary magnetic field which are generated by an injected current, and thus in the instant case, a magnitude of the external auxiliary magnetic field applied may be smaller than when the magnetization is varied by only the magnetic field.

Therefore, a magnetization switching is possible by only a magnetic field which is smaller than when only an external magnetic field is used according to the structure or material, and this refers that a permanent magnet providing a smaller magnetic field may be used.

Therefore, it is possible to fabricate a structure configured for performing a switching using only an alnico or ferrite magnet without using a permanent magnet made of a rare earth element which is currently a lot of issue.

A use example of the above-described magnetic sensor using an SOT of the present disclosure will be described below.

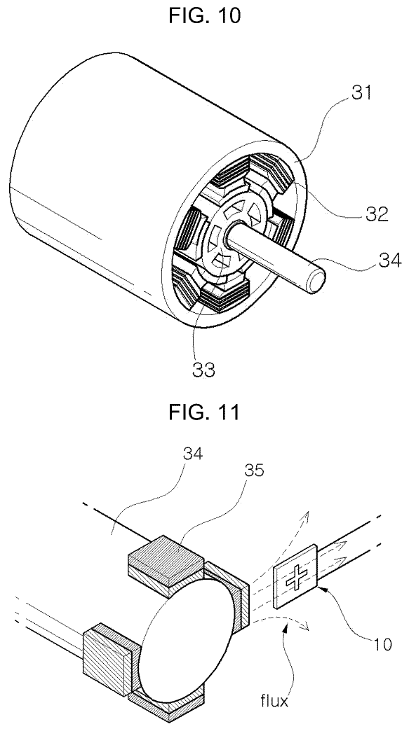

FIG. 10 is an example of a permanent magnet surface-attached type synchronous motor used in a traction motor for a vehicle. The traction motor includes a stator 31 and a rotor 33, and a rotational motion of the rotor 33 is controlled by applying an alternating current (AC) to a winding 32 of the stator 31. Generally, the rotor 33 is connected to a rotor shaft 34 to transmit rotation power to a gear or a wheel.

FIG. 11 is a schematic diagram illustrating a magnetic flux exerted on the SOT magnetic sensor 10 of the present disclosure after the rotor shaft 34 is extended and four permanent magnets 35 are attached to the extended rotor shaft 34 by alternating an N pole and an S pole. FIG. 11 illustrates an example of a magnetic flux emitted from one permanent magnet, and actual directions in which the magnetic flux enters and exits the permanent magnet are alternately shown according to polarity.

A direction of the sensor is determined so that a magnetic field acts in a direction parallel to a sensor surface, and because strength of the magnetic field generated by the permanent magnet is varied according to a distance, an arrangement of the sensor is located at a position at which strength of the magnetic field capable of performing a magnetization switching is applied when located in a center portion of the permanent magnet. Here, the magnetic field generated by the permanent magnet is configured as the external auxiliary magnetic field of FIG. 5 and FIG. 7.

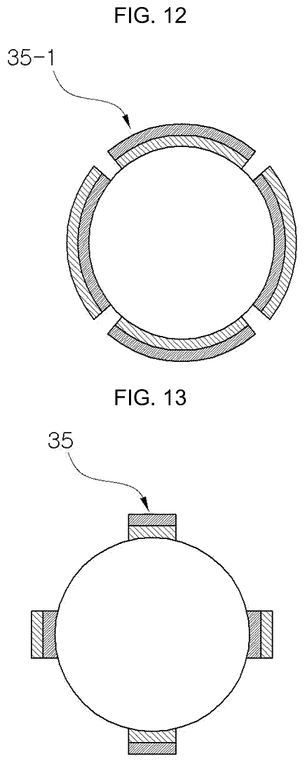

In the existing Hall sensor, because an output signal is varied when the magnetic field is removed, as shown in FIG. 12, a permanent magnet 35-1 should be manufactured to cover an entire surface of a shaft. However, when the magnetic sensor using an SOT of the present disclosure is switched once, because the switched state is maintained until a magnetic field having opposite polarity is applied, at least one pair of N-S poles needs to exist, and as shown in FIG. 13, the permanent magnet 35 may be locally located where a switchable magnetic field may be applied without the need to cover the entire surface of the shaft. Therefore, when the shaft extends and a separate permanent magnet is used, an operation is possible even using a very small amount of a permanent magnet.

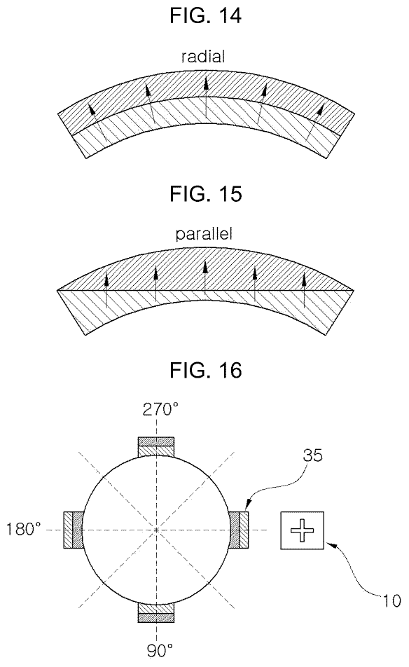

Furthermore, the magnetic flux may be differently generated according to magnetization of the permanent magnet which applies the magnetic flux to the sensor. When a C-shaped (arc-shaped) permanent magnet which surrounds the shaft is used, magnetization may be configured in two types which include a radial type of FIG. 14 and a parallel type of FIG. 15. In the sensor, the magnetic flux applied to the sensor from the center portion of the permanent magnet should be applied in a parallel state. Therefore, when a radial type permanent magnet of FIG. 14 is used, a position where a switching is started is on an edge portion of the radial type permanent magnet, and when a parallel type permanent magnet of FIG. 15 is used, a position where a switching is started is on the center portion of the parallel type permanent magnet. Therefore, when the output signal is applied, a surface area of the radial type permanent magnet should be considered in the case of FIG. 14.

FIG. 16 is a schematic diagram illustrating the case of FIG. 11 based on the position of the magnetic sensor 10. When an angle at which the magnetic sensor 10 is located is set to zero degrees, central positions of the permanent magnets 35 are located at a 90 degrees, a 180 degrees, a 270 degrees, and a 360 (=zero) degrees.

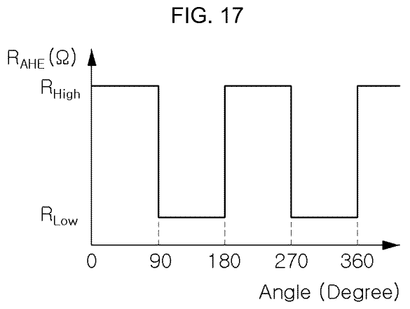

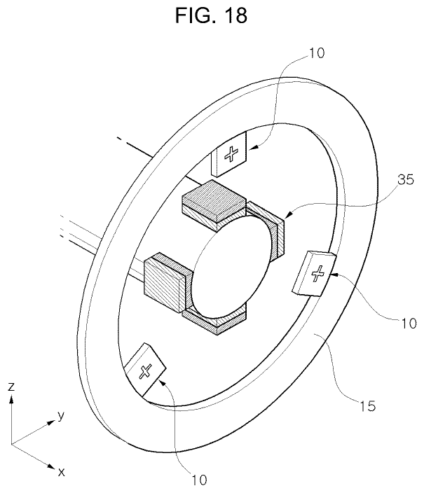

FIG. 17 is an example of a signal output from the magnetic sensor 10 when the rotor is rotated in a clockwise direction in the situation of FIG. 16. The output signal may be expressed as AHE resistance or a voltage and may exhibit a square wave according to a variation in polarity of the permanent magnet 35. When four permanent magnets are present, and when the rotor is rotated at 5,000 revolutions per minute (RPM), it takes 0.012 seconds per rotation, and in the instant case, a time tₚ₌₄ in which a pole is varied based on the center portion of the permanent magnet becomes three ms. Because tₚ₌₄ is 1.5 ms even when the rotor is rotated at 10,000 RPM, it is a time in which a magnetization switching occurs sufficiently, and thus 1.5 ms becomes a detectable range. (A magnetic switching occurs in units of several nanoseconds (ns)).

In the present example, a rotation speed (RPM) may be determined using that one rotation occurs when a signal variation occurs four times. Furthermore, because a distance and a time between center positions of the permanent magnets disposed at intervals of 90 degrees are known, it is possible to confirm a speed variation in a low-speed section. When the number of the permanent magnets is increased, the number of times the signal variation is also increased, and thus it is possible to confirm more precisely the speed variation.

Meanwhile, the existing Hall sensor or the existing magnetoresistance (MR) sensor utilizes a linear variation with respect to a magnetic field. Therefore, to obtain an output signal of a high-level or a low-level, a separate circuit configuration for converting a linear output signal into a binarized output signal is required.

However, as in the above example of the output data of FIG. 17, because a first output signal of the magnetic sensor using an SOT of the present disclosure is output as binary data, that is, a digital signal, a separate binarization operation is not required so that more simplified signal processing is possible.

As described above, when the number of sensors is increased in addition to the number of permanent magnets, an angle (position) of the permanent magnet according to the signal variation may be confirmed. The magnetic sensor may also be applied to a brushless direct current (BLDC) motor which is a typical motor using a Hall sensor as a position sensor.

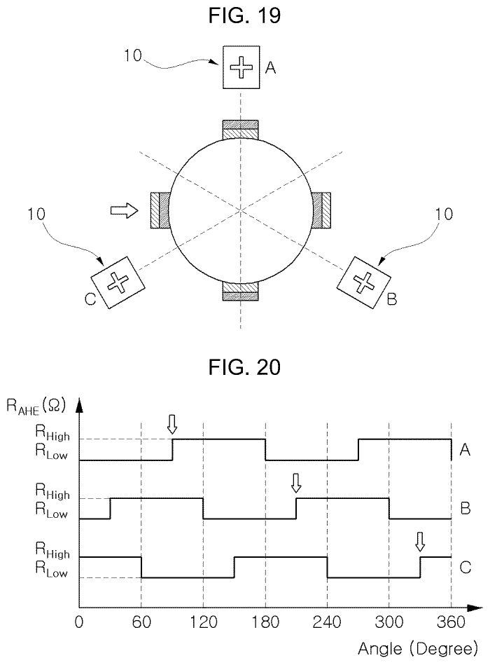

FIG. 18 illustrates a structure in which three magnetic sensors 10 using an SOT are concentrically disposed based on the rotor shaft 34. When the rotor shaft 34 to which the permanent magnets 35 are attached is rotated, the magnetic sensors 10 at positions A, B, and C shown in FIG. 19 may perform a magnetization switching due to magnetic fields generated by the permanent magnets 35 to output square waves shown in FIG. 20.

An arrow in FIG. 20 refers to a signal variation when the permanent magnet indicated by an arrow in FIG. 19 passes.

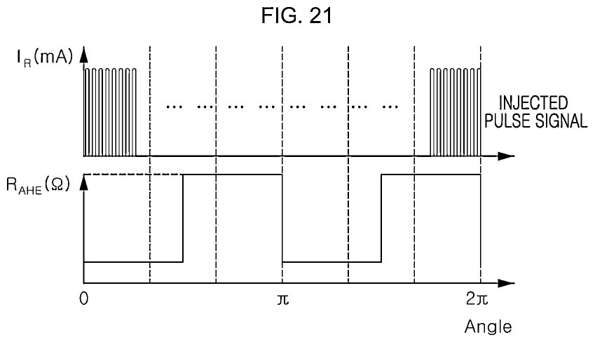

A common method of detecting a position is as follows. When a specific square wave shown in FIG. 20 is obtained at 2π (360 degrees) as one period, as shown in FIG. 21, a pulse having a constant period is injected using a digital signal processor (DSP) instead of a continuous current. In the instant case, strength of the pulse is I_{R} in which a switching may occur, and a pulse width may also be different according to a device, but the pulse width is injected in several to tens of microseconds (μs). Therefore, when an initial position (angle) θ₀ and an angular velocity ω, and a rotation time t of the rotor are known, a position of the rotor may become θ=θ₀+ωt. Here, θ₀ may be a last position stored in an internal memory of the motor when used before or θ₀ may be used by matching the position of the sensor to the position of the permanent magnet in the case of a first use to be set as zero. Because ω may be expressed as 2πf and f is known by an injected pulse width, θ₀ may be known by counting the number of injected pulses while a single resistance state is maintained. The above case is an example using a signal output from one sensor, and because resolution for an electric angle is improved as the number of sensors is increased, precision is improved.

In accordance with the present disclosure, because a phenomenon in which magnetization is switched in response to a variation in polarity of an external magnetic field is used, a binary signal is output so that it is possible to very rapidly respond to the variation in polarity of the external magnetic field and signal processing may be simplified when compared with a linear magnetic field sensor such as the existing Hall sensor or the existing magnetoresistance (MR) sensor.

Furthermore, when compared with a magnetoresistance switching which utilizes only an external magnetic field to vary magnetization, a spin-orbit torque (SOT) switching allows a variation in magnetization switching using only a lower magnetic field so that a permanent magnet generating a relatively low magnetic force may be used.

Furthermore, because a magnetization state is maintained until an external magnetic field including a different polarity is applied, a magnetic sensor may be driven using a permanent magnet having a very small surface area (reduction in use amount of permanent magnets).

For convenience in explanation and accurate definition in the appended claims, the terms “upper”, “lower”, “inner”, “outer”, “up”, “down”, “upwards”, “downwards”, “front”, “rear”, “back”, “inside”, “outside”, “inwardly”, “outwardly”, “interior”, “exterior”, “internal”, “external”, “forwards”, and “backwards” are used to describe features of the exemplary embodiments with reference to the positions of such features as displayed in the figures. It will be further understood that the term “connect” or its derivatives refer both to direct and indirect connection.

The foregoing descriptions of specific exemplary embodiments of the present disclosure have been presented for purposes of illustration and description. They are not intended to be exhaustive or to limit the present disclosure to the precise forms disclosed, and obviously many modifications and variations are possible in light of the above teachings. The exemplary embodiments were chosen and described to explain certain principles of the present disclosure and their practical application, to enable others skilled in the art to make and utilize various exemplary embodiments of the present disclosure, as well as various alternatives and modifications thereof. It is intended that the scope of the present disclosure be defined by the Claims appended hereto and their equivalents.

What is claimed is:

1. A magnetic sensor using a spin-orbit torque (SOT), the magnetic sensor comprising:
an SOT channel layer made of a heavy metal material;
a ferromagnetic layer stacked on the SOT channel layer; and
a protective layer stacked on the ferromagnetic layer,
wherein the SOT is generated due to a current applied to the SOT channel layer to vary magnetization of the ferromagnetic layer,
further including:
a sensing portion configured to measure a voltage of a component parallel to a flat surface formed by the ferromagnetic layer and perpendicular to a direction of the current,
a permanent magnet disposed adjacent to the magnetic sensor,
wherein polarity of the permanent magnet facing the magnetic sensor is changeable,
wherein a magnetization switching of the ferromagnetic layer occurs by an external auxiliary magnetic field generated by the permanent magnet in a direction parallel to the direction of the current after the SOT occurs,
wherein a magnetization state of the ferromagnetic layer is maintained unless no change in direction of the external auxiliary magnetic field,
wherein the polarity of the permanent magnet facing the magnetic sensor changes and a direction of the external auxiliary magnetic field changes to a direction antiparallel to a previous direction, thereby the magnetization of the ferromagnetic layer occurs again.

2. The magnetic sensor of claim 1, wherein the ferromagnetic layer is made of a magnetic anisotropy material, and is magnetized in a perpendicular direction.

3. The magnetic sensor of claim 2, wherein the varied magnetization of the ferromagnetic layer is in a direction perpendicular to the flat surface formed by the ferromagnetic layer.

4. The magnetic sensor of claim 1,
wherein a waveform of the voltage measured by the sensing portion is a rectangular waveform.

5. The magnetic sensor of claim 1,
wherein the SOT channel layer, the ferromagnetic layer and the protective layer are in a form of a cross, and a measurement terminal is connected to at least two end portions of the protective layer.

6. The magnetic sensor of claim 1, wherein a measurement terminal connected to the channel layer to measure the voltage includes a metal layer made of Ta, Ti, or Cr and is deposited on a bottom portion of the measurement terminal.

7. The magnetic sensor of claim 1, further including:
a buffer layer for increasing adhesive strength to a wafer below the SOT channel layer.

8. The magnetic sensor of claim 1,
wherein the ferromagnetic layer is made of Co or CoFeB,
wherein the SOT channel layer is made of the heavy metal material including Ta, Pt, W, or Hf, and
wherein the protective layer is made of MgO, Ru, or Ta.

9. A sensing method of the magnetic sensor using the spin-orbit torque (SOT), the sensing method comprising:
applying the current to the SOT channel layer of the magnetic sensor using the SOT of claim 1,
after the SOT occurs, applying the external auxiliary magnetic field in the direction parallel to the direction of the current; and
measuring the voltage of a component parallel to the flat surface formed by the ferromagnetic layer and perpendicular to the direction of the current.

10. The sensing method of claim 9, wherein the ferromagnetic layer is made of a magnetic anisotropy material, and is magnetized in a perpendicular direction.
